(19) United States
(12) Patent Application Publication
(10) Pub. No.: US 2025/0201476 A1
(43) Pub. Date: Jun. 19, 2025

(54) MULTILAYER CERAMIC ELECTRONIC COMPONENT, PACKAGE BODY, AND CIRCUIT BOARD

(71) Applicant: TAIYO YUDEN CO., LTD., Tokyo (JP)

(72) Inventors: Hiroaki SATO, Takasaki-shi (JP); Yuya MOTEGI, Takasaki-shi (JP)

(21) Appl. No.: 19/071,377

(22) Filed: Mar. 5, 2025

Related U.S. Application Data
(63) Continuation of application No. PCT/JP2023/035910, filed on Oct. 2, 2023.

(30) Foreign Application Priority Data
Oct. 5, 2022 (JP) 2022-161172

(51) Int. Cl. H01G 4/224; H01G 2/06; H01G 4/232; H01G 4/30; H05K 1/18

(52) U.S. Cl. CPC H01G 4/224; H01G 2/065; H01G 4/232; H05K 1/181; H01G 4/30; H05K 2201/10015

(57) ABSTRACT

A multilayer ceramic electronic component includes a laminate body having a pair of principal faces orthogonal to a Z axis, a pair of end faces orthogonal to an X axis, and a pair of lateral faces orthogonal to a Y axis; a first margin part provided at one side of the laminate body in a Y-axis direction; a second margin part provided at another side of the laminate body in the Y-axis direction; and a pair of external electrodes provided on the pair of respective end faces. The external electrodes each include an extended portion extended to a plane of the first margin part that is defined by a Z-axis direction and an X-axis direction. At least the first margin part has a dimension in the Z-axis direction that is set greater than a dimension of the laminate body in the Z-axis direction.

### CROSS-REFERENCE TO RELATED APPLICATIONS

The present application claims priority to Japanese Patent Application No. 2022-161172, filed Oct. 5, 2022, the disclosure of which is incorporated herein by reference in its entirety including any and all particular combinations of the features disclosed therein.

### BACKGROUND OF THE INVENTION

### 1. Field of the Invention

The present invention relates to a multilayer ceramic electronic component, a package body, and a circuit board.

### 2. Description of the Related Art

Electronic components, such as multilayer ceramic capacitors (MLCCs), included in recent-year electronic apparatuses provided with increasingly high performance tend to have increased capacities and high-density mounting on substrates (Japanese Unexamined Patent Application Publication No. 2014-220476, for example).

A multilayer ceramic electronic component is mounted on a substrate with a pair of external electrodes each connected to the substrate. Here, a lamination direction in which internal electrodes and ceramic layers of the multilayer ceramic electronic component are laminated is defined as a thickness direction, and a direction orthogonal to the thickness direction is defined as a width direction. Under such definitions, the external electrodes are provided on the two respective ends in a length direction, which is orthogonal to both the thickness direction and the width direction. Such a multilayer ceramic electronic component that is mounted on a mounting face of a substrate may take a first mounting mode in which a plane defined by the width direction and the length direction extends parallel to the mounting face. Alternatively, the multilayer ceramic electronic component may take a second mounting mode in which a plane defined by the thickness direction and the length direction extends parallel to the mounting face. If the multilayer ceramic electronic component has a thickness-direction dimension smaller than the width-direction dimension thereof and takes the second mounting mode, the connection area between each of the external electrodes and the substrate becomes small. In such a case, coupled with the increased height of multilayer ceramic electronic components, it becomes difficult for multilayer ceramic electronic components to become stable.

### SUMMARY OF THE INVENTION

Accordingly, an object of the present invention is to provide a multilayer ceramic electronic component that is stably mountable on a circuit board.

To achieve the above object, a multilayer ceramic electronic component of the present invention comprises: a laminate body (e.g., roughly rectangular parallelepiped) including a plurality of ceramic layers that are laminated in a first axial direction, a plurality of internal electrodes that are located between the ceramic layers and that form a capacitance-forming part in combination with the ceramic layers, a pair of principal faces that are located opposite to each other in the first axial direction, a pair of lateral faces that are located opposite to each other in a second axial direction orthogonal to the first axial direction, and a pair of end faces that are located opposite to each other in a third axial direction orthogonal to the first axial direction and to the second axial direction; a first margin part provided at one side of the laminate body in the second axial direction; a second margin part provided at another side of the laminate body in the second axial direction; and a pair of external electrodes provided on the pair of respective end faces. The pair of external electrodes each include an extended portion extended to at least a plane of the first margin part, the plane being defined by the first axial direction and the third axial direction. At least the first margin part of the two margin parts has a dimension in the first axial direction that is set greater than a dimension of the laminate body in the first axial direction. Also the first margin part has a dimension in the third axial direction that is set substantially equal to a dimension of the laminate body in the third axil direction, i.e., a dimension of the first margin part in the third axial direction is set in a manner that the first margin part is flush with the pair of end faces of the laminate. In the disclosure, “substantially equal” or the like may refer to an immaterial difference, less than a detectable difference, a difference that does not materially affect the target or intended properties, or a difference recognized by a skilled artisan within manufacture irregularity or manufacture variation.

In the multilayer ceramic electronic component, the dimension of the first margin part in the first axial direction may be 105% to 110% of the dimension of the laminate body in the first axial direction.

Also, in the multilayer ceramic electronic component, the second margin part may have a dimension in the first axial direction that is set greater than the dimension of the laminate body in the first axial direction.

Further, in the multilayer ceramic electronic component, the first margin part may have a dimension in the second axial direction that is set greater than a dimension of the second margin part in the second axial direction.

To achieve the above object, a package body comprises: the multilayer ceramic electronic component according to the above configurations; a carrier tape having a sealing surface that is perpendicular to the second axial direction, and a recessed part that is recessed relative to the sealing surface in the second axial direction and that accommodates the multilayer ceramic electronic component; and a top tape pasted to the sealing surface and covering the recessed part.

To achieve the above object, a circuit board of the present invention including a substrate; and the multilayer ceramic electronic component according to the above configurations that is mounted on the substrate. The second axial direction of the multilayer ceramic electronic component coincides with a direction perpendicular to a mounting face of the substrate. The extended portion included in the first margin part is placed on a terminal part provided on the mounting face.

### Effects of the Present Invention

According to the present disclosure, in some embodiments, a multilayer ceramic electronic component that is stably mountable on a circuit board can be provided.

### BRIEF DESCRIPTION OF THE DRAWINGS

FIG. 1 is a perspective view of a multilayer ceramic capacitor according to a first embodiment.

FIG. 2 is a cross-sectional view of the multilayer ceramic capacitor according to the first embodiment, taken along line A-A given in FIG. 1.

FIG. 3 is a cross-sectional view of the multilayer ceramic capacitor according to the first embodiment, taken along line B1-B1 given in FIG. 1.

FIG. 4 is a perspective view of a circuit board including the multilayer ceramic capacitor according to the first embodiment.

FIG. 5 is a plan view of a part of a package body.

FIG. 6 is a cross-sectional view of the package body, taken along line C-C.

FIGS. 7A and 7B illustrate steps included in a method of manufacturing the multilayer ceramic capacitor according to the first embodiment.

FIGS. 8A and 8B illustrate other steps included in the method of manufacturing the multilayer ceramic capacitor according to the first embodiment.

FIG. 9 outlines another method of manufacturing the multilayer ceramic capacitor according to the first embodiment.

FIG. 10 is a perspective view of a multilayer ceramic capacitor according to a second embodiment.

FIG. 11 is a cross-sectional view of the multilayer ceramic capacitor according to the second embodiment, taken along line B2-B2 given in FIG. 10.

FIG. 12 is a cross-sectional view of a multilayer ceramic capacitor according to a third embodiment.

FIG. 13 illustrates a step included in a method of manufacturing the multilayer ceramic capacitor according to the third embodiment.

FIG. 14 outlines another method of manufacturing the multilayer ceramic capacitor according to the third embodiment.

### DESCRIPTION OF THE PREFERRED EMBODIMENTS

Embodiments of the present invention will now be described with reference to the accompanying drawings. The drawings are not necessarily to scale (i.e., the dimensions, ratios, etc. are shown in some drawings for illustrative purposes, and do not accurately represent those of the actual products, while some drawings represent accurate dimensions, ratios, etc. in some embodiments). As a matter of illustration, details of some components or such components themselves are omitted in some of the drawings. It should be noted that some of the drawings are given, as appropriate, an X axis, a Y axis, and a Z axis that are orthogonal to each other. The X axis, the Y axis, and the Z axis define a fixed coordinate system that is fixed for a corresponding multilayer ceramic capacitor. In the following description, a Z-axis direction corresponds to a first axial direction, a Y-axis direction corresponds to a second axial direction, and an X-axis direction corresponds to a third axial direction.

### First Embodiment

### Configuration of Multilayer Ceramic Capacitor 10

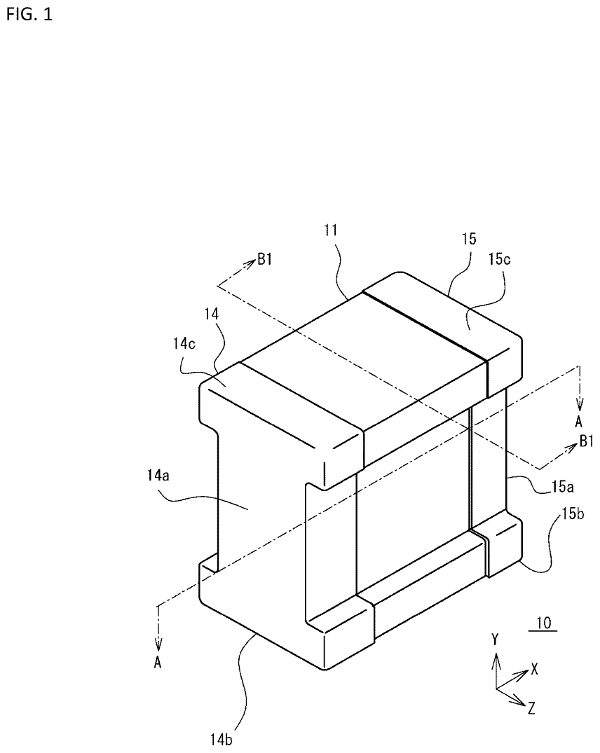

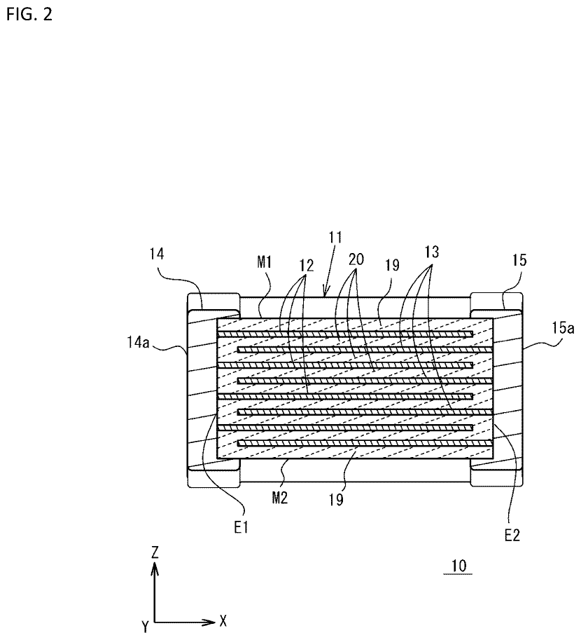

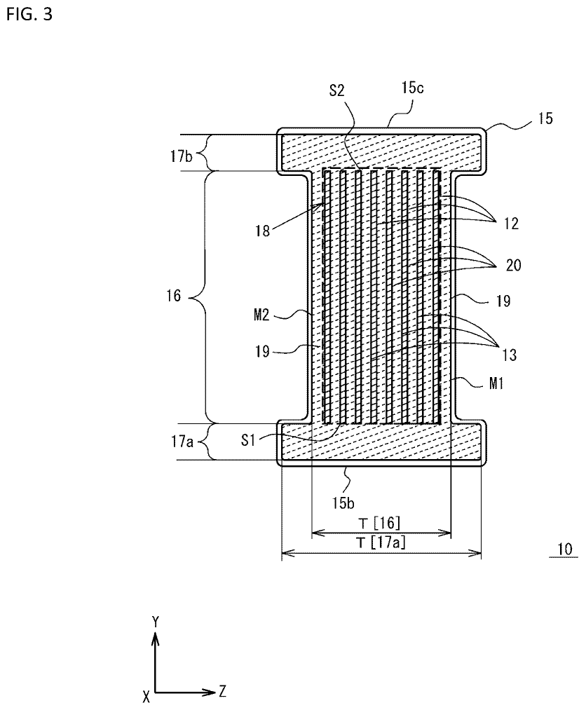

Referring to FIGS. 1 to 3, a multilayer ceramic capacitor 10 according to a first embodiment will first be described. FIG. 1 is a perspective view of the multilayer ceramic capacitor 10. FIG. 2 is a cross-sectional view of the multilayer ceramic capacitor 10, taken along line A-A given in FIG. 1. FIG. 3 is a cross-sectional view of the multilayer ceramic capacitor 10, taken along line B1-B1 given in FIG. 1.

The multilayer ceramic capacitor 10 includes a ceramic element body 11, a first external electrode 14, and a second external electrode 15. The ceramic element body 11 includes a laminate body 16 (see FIG. 3). The laminate body 16 has first and second end faces E1 and E2, which are orthogonal to the X axis; first and second lateral faces S1 and S2, which are orthogonal to the Y axis; and first and second principal faces M1 and M2, which are orthogonal to the Z axis. The first and second lateral faces S1 and S2 are hidden inside the ceramic element body 11, whereas the first and second end faces E1 and E2 and the first and second principal faces M1 and M2 are exposed to the outside of the ceramic element body 11. Therefore, in the following description, the first and second end faces E1 and E2 and the first and second principal faces M1 and M2 are occasionally referred to as, for example, first and second end faces E1 and E2 of the ceramic element body 11 and first and second principal faces M1 and M2 of the ceramic element body 11, respectively.

The external electrodes 14 and 15 cover the first and second end faces E1 and E2 of the ceramic element body 11 and are located across the ceramic element body 11 from each other in the X-axis direction. The first external electrode 14 has a first face portion 14a, which covers the first end face E1 (see FIG. 2); a second face portion 14b, which serves as an extended portion that extends continuously to one of lateral faces of the ceramic element body 11 (i.e., one of lateral faces of margin parts discussed below); and a third face portion 14c, which serves as another extended portion that extends continuously to the other of the lateral faces of the ceramic element body 11 (i.e., the other of lateral faces of the margin parts). The second face portion 14b and the third face portion 14c each are formed in a plane defined by the Z-axis direction and the X-axis direction. Likewise, the second external electrode 15 has a first face portion 15a, which covers the second end face E2 (see FIG. 2); a second face portion 15b, which serves as an extended portion that extends continuously to one of the lateral faces of the ceramic element body 11; and a third face portion 15c, which serves as another extended portion that extends continuously to the other of the lateral faces of the ceramic element body 11. The second face portion 15b and the third face portion 15c each are formed in a plane defined by the Z-axis direction and the X-axis direction. In the present embodiment, the second face portions 14b and 15b are to be connecting portions connected to a substrate when being mounted thereon, which are described in detail separately below.

The external electrodes 14 and 15 are each made of a good electrical conductor. Examples of the good electrical conductor forming the external electrodes 14 and 15 include metals and alloys mainly composed of one or more of copper (Cu), nickel (Ni), tin (Sn), palladium (Pd), platinum (Pt), silver (Ag), gold (Au), and the like.

The ceramic element body 11 is made of dielectric ceramic and includes the laminate body 16, a first margin part 17a, and a second margin part 17b. The laminate body 16 has the first and second lateral faces S1 and S2, which each face the Y-axis direction. The first margin part 17a is located at the first lateral face S1. The second margin part 17b is located at the second lateral face S2. As described above, the laminate body 16 has the first and second end faces E1 and E2, which face the X-axis direction; and the first and second principal faces M1 and M2, which face the Z-axis direction. It should be noted that the first and second end faces E1 and E2 of the laminate body 16 coincide with the two respective end faces of the ceramic element body 11, and the first and second principal faces M1 and M2 of the laminate body 16 coincide with the two respective principal faces of the ceramic element body 11.

The laminate body 16 includes a plurality of flat plate-like ceramic layers 20, which each extend in an X-Y plane and are laminated in the Z-axis direction. The laminate body 16 includes a capacitance-forming part 18 and covering portions 19. The covering portions 19 cover the capacitance-forming part 18 from the two respective sides in the Z-axis direction, thereby forming the first and second principal faces M1 and M2 of the laminate body 16. It should be noted that in FIG. 3, the capacitance-forming part 18 is illustrated as an area enclosed by a broken line.

The capacitance-forming part 18 includes a plurality of first and second internal electrodes 12 and 13, which are present between the plurality of ceramic layers 20 and are each in the form of a sheet extending along an X-Y plane. The internal electrodes 12 and 13 are arranged alternately in the Z-axis direction. That is, one internal electrode 12 and one internal electrode 13 face each other via one ceramic layer 20 in the Z-axis direction. It should be noted that the numbers of the first and second internal electrodes 12 and 13 that are laminated as illustrated in relevant drawings are not necessarily the same as the actual numbers of the internal electrodes 12 and 13.

The first internal electrodes 12 are extracted to the first end face E1 covered by the first external electrode 14. On the other hand, the second internal electrodes 13 are extracted to the second end face E2 covered by the second external electrode 15. Accordingly, the first internal electrodes 12 are connected only to the first external electrode 14, whereas the second internal electrodes 13 are connected only to the second external electrode 15.

The internal electrodes 12 and 13 each extend over the entire width of the capacitance-forming part 18 in the Y-axis direction and are therefore exposed at the lateral faces S1 and S2 of the laminate body 16. The first margin part 17a covers the first lateral face S1 of the laminate body 16. The second margin part 17b covers the second lateral face S2 of the laminate body 16. Thus, the internal electrodes 12 and 13 are assuredly insulated from each other at the two lateral faces S1 and S2 of the laminate body 16.

In the multilayer ceramic capacitor 10 configured as above, when a voltage is applied between the first external electrode 14 and the second external electrode 15, the voltage is applied to the plurality of ceramic layers 20 that are present between the first internal electrodes 12 and the second internal electrodes 13. Thus, the multilayer ceramic capacitor 10 stores an electric charge of an amount corresponding to the voltage applied between the first external electrode 14 and the second external electrode 15.

The ceramic element body 11 is made of a dielectric ceramic that has a high dielectric constant so that an increased capacity is produced in the ceramic layers 20 that are present between the internal electrodes 12 and 13.

For example, the ceramic layers 20 have a main phase that is a ceramic material having a perovskite structure represented by a general formula of ABO₃. Herein, the perovskite structure encompasses a structure represented by ABO_{3-α}, which does not conform to the stoichiometric composition. For example, the ceramic material to be used may be selected at least one from the following: barium titanate (BaTiO₃), calcium zirconate (CaZrO₃), calcium titanate (CaTiO₃), strontium titanate (SrTiO₃), magnesium titanate (MgTiO₃), Ba_{1-x-y}CaₓSr_{y}Ti_{1-z}Zr₂O₃ (0≤x≤1, 0≤y≤1, 0≤z≤1) that has a perovskite structure, and the like. Examples of Ba_{1-x-y}CaₓSr_{y}Ti_{1-z}Zr₂O₃ include barium strontium titanate, barium calcium titanate, barium zirconate, barium zirconate titanate, calcium titanate zirconate, and barium calcium titanate zirconate.

The ceramic layers 20 may contain one or more of the following additives: oxides of magnesium (Mg), manganese (Mn), molybdenum (Mo), vanadium (V), chromium (Cr), and rare earth elements (yttrium (Y), samarium (Smi), europium (Eu), gadolinium (Gd), terbium (Tb), dysprosium (Dy), holmium (Ho), erbium (Er), thulium (Tm), and ytterbium (Yb)); oxides containing one or more of cobalt (Co), nickel (Ni), lithium (Li), boron (B), sodium (Na), potassium (K), and silicon (Si); and glasses containing one or more of cobalt, nickel, lithium, boron, sodium, potassium, and silicon. The thickness of each of the ceramic layers 20 may be set as appropriate but is set to 2 μm in the present embodiment.

The internal electrodes 12 and 13 are each made of a good electrical conductor. Examples of the good electrical conductor forming the internal electrodes 12 and 13 include nickel (Ni) typically, and other metals and alloys mainly composed of any of copper (Cu), palladium (Pd), platinum (Pt), silver (Ag), gold (Au), and the like.

Now, the first margin part 17a and the second margin part 17b will be described. Referring to FIG. 3, the first margin part 17a has a dimension T[17a] in the Z-axis direction that is greater than a dimension T[16] of the laminate body 16, intersecting the first margin part 17a, in the Z-axis direction. Thus, the area of the second face portion 15b of the second external electrode 15 is widened. Likewise, the area of the second face portion 14b of the first external electrode 14, not illustrated in FIG. 3, is also widened. The second margin part 17b has the same dimension as the first margin part 17a in the Z-axis direction. Accordingly, the second margin part 17b has a dimension in the Z-axis direction that is greater than the dimension T[16] of the laminate body 16 in the Z-axis direction.

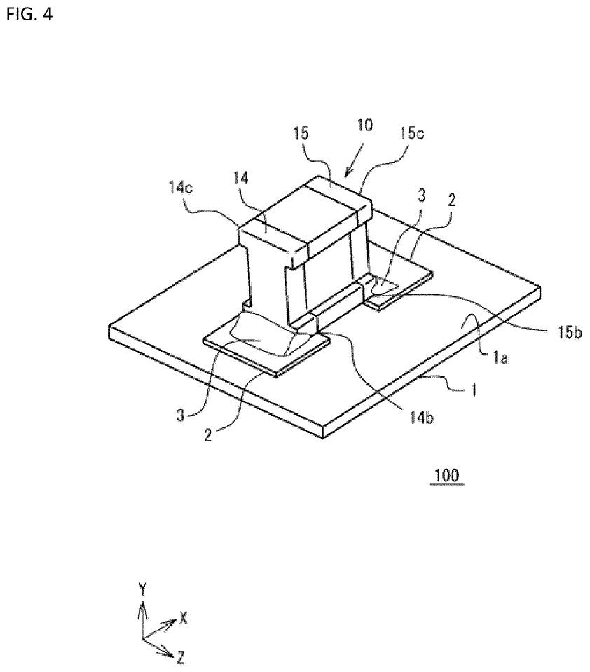

Referring now to FIG. 4, a circuit board 100 including the multilayer ceramic capacitor 10 will be described. It should be noted that the coordinate system given in FIG. 4 is set for the multilayer ceramic capacitor 10 and is not set with reference to a mounting face 1a of a substrate 1 included in the circuit board 100.

The multilayer ceramic capacitor 10 is placed on lands 2, which serve as terminal parts provided on the mounting face 1a of the substrate 1. The multilayer ceramic capacitor 10 is fixed to the lands 2 with solder 3. In such a state, the Y-axis direction of the multilayer ceramic capacitor 10 coincides with a direction perpendicular to the mounting face 1a of the substrate 1. The multilayer ceramic capacitor 10 is mounted such that the second face portions 14b and 15b of the first and second external electrodes 14 and 15 are connected to the respective lands 2.

The first margin part 17a and the second margin part 17b each have a dimension in the Z-axis direction that is greater than the dimension T[16] of the laminate body 16 in the Z-axis direction. Thus, the areas of the second face portions 14b and 15b are widened. Therefore, the multilayer ceramic capacitor 10 is stably mountable on the substrate 1.

It should be noted that in the multilayer ceramic capacitor 10 according to the present embodiment, the areas of the third face portions 14c and 15c are also widened as in the same manner as the areas of the second face portions 14b and 15b. Therefore, the multilayer ceramic capacitor 10 may be rotated by 180° such that the third face portions 14c and 15c are connected to the lands 2.

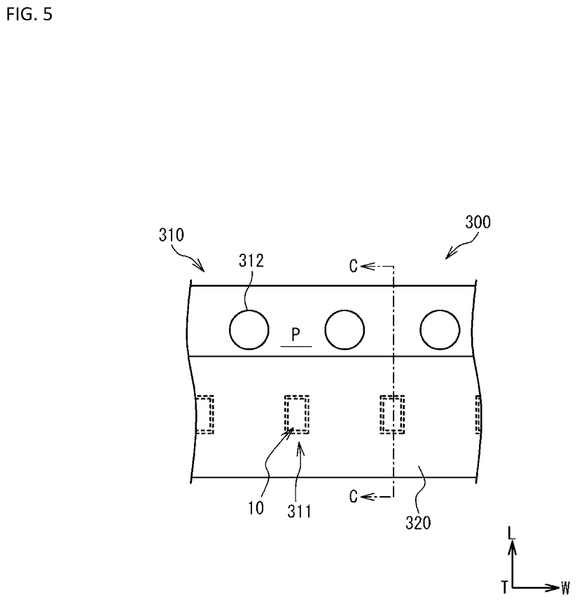

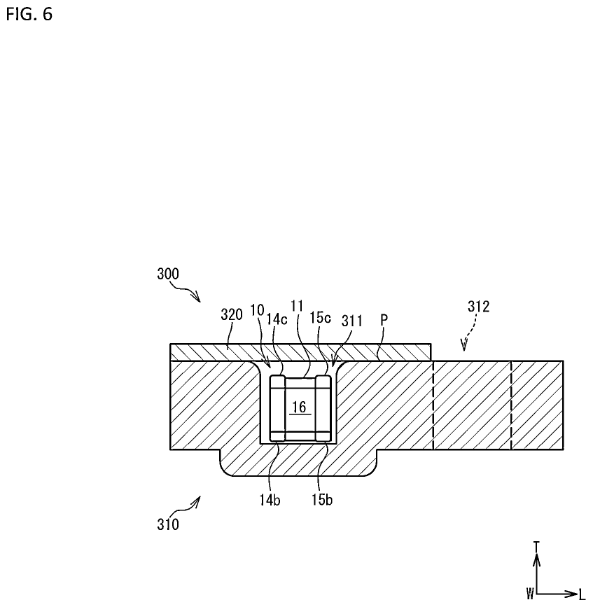

Such multilayer ceramic capacitors 10 to be mounted on substrates 1 are prepared in a package as package body 300. FIGS. 5 and 6 illustrate an example of the package body 300. FIG. 5 is a plan view of a part of the package body 300. FIG. 6 is a cross-sectional view of the package body 300, taken along line C-C given in FIG. 5.

The package body 300 includes multilayer ceramic capacitors 10, a carrier tape 310, and a top tape 320. The carrier tape 310 is a piece of tape elongated in a W direction (see FIGS. 5 and 6). The carrier tape 310 has a plurality of recessed parts 311, which are arranged at intervals in the W direction and accommodate the multilayer ceramic capacitors 10, respectively.

The carrier tape 310 has a sealing surface P, which faces upward orthogonally to a T direction (see FIGS. 5 and 6). The plurality of recessed parts 311 are recessed relative to the sealing surface P downward in the T direction. That is, the carrier tape 310 is designed in such a manner as to allow the multilayer ceramic capacitors 10 in the plurality of recessed parts 311 to be taken out from the side of the sealing surface P.

The carrier tape 310 further has a plurality of feed holes 312, which each pass through the carrier tape 310 in the T direction. The feed holes 312 are arranged at intervals in the W direction and are staggered from the plurality of recessed parts 311 in an L direction (see FIGS. 5 and 6). The feed holes 312 serve as engagement holes intended for a tape transfer mechanism to transfer the carrier tape 310 in the W direction.

In the package body 300, the top tape 320 is pasted to the sealing surface P of the carrier tape 310 along the row of the plurality of recessed parts 311 in such a manner as to cover all of the plurality of recessed parts 311 accommodating the plurality of multilayer ceramic capacitors 10. Thus, the plurality of multilayer ceramic capacitors 10 are retained in the plurality of recessed parts 311.

As illustrated in FIG. 6, the multilayer ceramic capacitors 10 in the recessed parts 311 of the carrier tape 310 are each oriented such that a surface of the ceramic element body 11 facing in the same direction as the third surface portions 14c and 15c faces the top tape 320, while an another surface of the ceramic element body 11 facing in the same direction as the second face portions 14b and 15b faces the bottom face of the recessed part 311.

To mount the multilayer ceramic capacitors 10 packed in the package body 300, the top tape 320 is released from the sealing surface P of the carrier tape 310 in the W direction. Thus, the plurality of recessed parts 311 of the package body 300 accommodating the plurality of multilayer ceramic capacitors 10 are sequentially opened on the upper side in the T direction.

Each of the multilayer ceramic capacitors 10 accommodated in the recessed parts 311 thus opened is taken out with a side of the ceramic element body 11 where the third face portions 14c and 15c are located being sucked to the tip of a suction nozzle included in a mounting device. The mounting device moves the suction nozzle to move the multilayer ceramic capacitor 10 to a position above the mounting face 1a (see FIG. 4) of the substrate 1.

Subsequently, the mounting device brings the second face portions 14b and 15b of the multilayer ceramic capacitor 10 to face the mounting face 1a and places the external electrodes 14 and 15 onto the pair of lands 2 having solder paste applied thereto. In this state, the mounting device stops the suction applied to the ceramic element body 11 through the suction nozzle. Thus, the multilayer ceramic capacitor 10 is placed on the mounting face 1a.

Subsequently, a capacitor-mounted substrate wherein the multilayer ceramic capacitors 10 is placed on the mounting face 1a is, for example, loaded in a reflow furnace, whereby a solder paste is melted. Then, the melted solder paste is cured. The cured solder paste connects the external electrodes 14 and 15 to the pair of lands 2. Thus, the circuit board 100 illustrated in FIG. 4 is obtained.

The multilayer ceramic capacitor 10 according to the present embodiment has dimensions conforming to a so-called size 0603. Specifically, the multilayer ceramic capacitor 10 has a dimension L in the X-axis direction of 0.6 mm, a dimension T in the Z-axis direction of 0.3 mm, and a dimension W in the Y-axis direction of 0.5 mm. As a matter of convenience, the above dimensions T and W do not include the thicknesses of the external electrodes 14 and 15. In the multilayer ceramic capacitor 10 designed as above, referring to FIG. 3, the dimension T[17a] of the first margin part 17a in the Z-axis direction is set to 0.3 mm, and the dimension T[16] of the laminate body 16 in the Z-axis direction is set to 0.27 mm. The dimension T[17a] of the second margin part 17b in the Z-axis direction is also set to 0.3 mm. Such dimensions are only exemplary, and the embodiment is not limited thereto.

### Manufacturing Method 1

A method of manufacturing the multilayer ceramic capacitor 10 will now be described. The first margin part 17a and the second margin part 17b included in the multilayer ceramic capacitor 10 each have a dimension in the Z-axis direction that is greater than the dimension T[16] of the laminate body 16 in the Z-axis direction. The following description relates to components whose shapes are specific to the multilayer ceramic capacitor 10 according to the present embodiment.

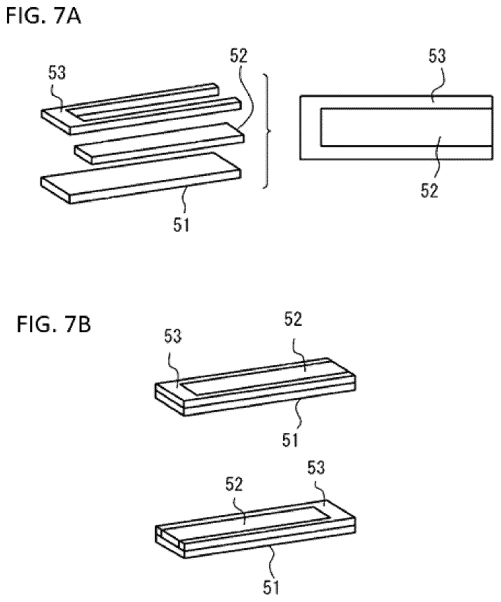

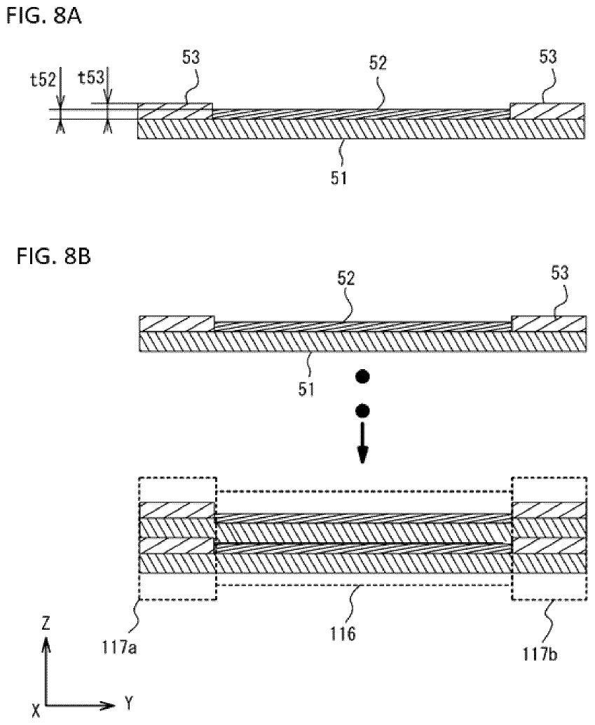

The multilayer ceramic capacitor 10 is manufacturable with an application of a publicly known method of manufacturing a multilayer ceramic capacitor. FIGS. 7A and 7B illustrate a dielectric green sheet 51, an internal-electrode pattern 52, and a dielectric pattern 53, which are prepared for forming the laminate body 16, the first margin part 17a, and the second margin part 17b. The dielectric green sheet 51, the internal-electrode pattern 52, and the dielectric pattern 53 constitute a lamination unit. Such lamination units are laminated to form a laminate body 116, which corresponds to the laminate body 16; and a first margin part 117a and a second margin part 117b (see FIG. 8B), which correspond to the first margin part 17a and the second margin part 17b.

The dielectric pattern 53 is obtained through printing in which dielectric-pattern paste is applied to a peripheral area of the dielectric green sheet 51 where the internal-electrode pattern 52 is absent. Thus, the dielectric pattern 53 fills the step difference between the dielectric green sheet 51 and the internal-electrode pattern 52. In the present embodiment, as illustrated in FIG. 8A, the internal-electrode pattern 52, which has a thickness t52, is thinner than the dielectric pattern 53, which has a thickness t53. Therefore, laminating such lamination units sequentially as illustrated in FIG. 8B provides the first margin part 117a and the second margin part 117b, which are each thicker than the laminate body 116. These components are sintered, and then external electrodes 14 and 15 are formed thereon. Thus, a multilayer ceramic capacitor 10 is obtained.

### Manufacturing Method 2

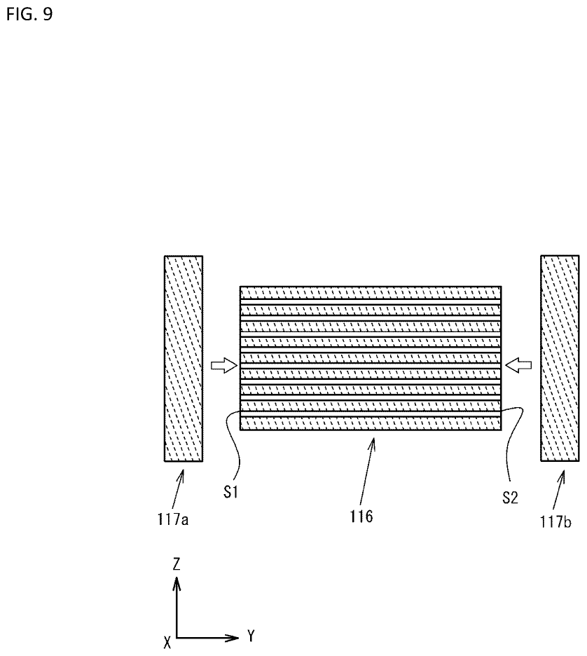

Referring to FIG. 9, another method of manufacturing the multilayer ceramic capacitor 10 will now be described. The manufacturing method illustrated in FIG. 9 is an application of a sheet-pasting method.

In such a manufacturing method, a laminate body 116 that is yet to be fired and a first margin part 117a and a second margin part 117b that are each in a sheet form and yet to be fired are first prepared through publicly known methods. In this step, the dimensions of the first margin part 117a and the second margin part 117b in the Z-axis direction are each set greater than the dimension of the laminate body 116 in the Z-axis direction. The first margin part 117a and the second margin part 117b prepared as above are pressed against the first lateral face S1 and the second lateral face S2, respectively, of the laminate body 116 and are thus pasted thereto. Subsequently, the resulting body obtained as above is fired, and external electrodes 14 and 15 are formed thereon. Thus, a multilayer ceramic capacitor 10 is obtained.

In the multilayer ceramic capacitor 10 according to the present embodiment, the dimensions of the margin parts 17a and 17b in the Z-axis direction are each greater than the dimension of the laminate body 16 in the Z-axis direction. Correspondingly, the second face portions 14b and 15b and the third face portions 14c and 15c have increased areas. Consequently, the multilayer ceramic capacitor 10 is stably mountable on a substrate 1.

### Second Embodiment

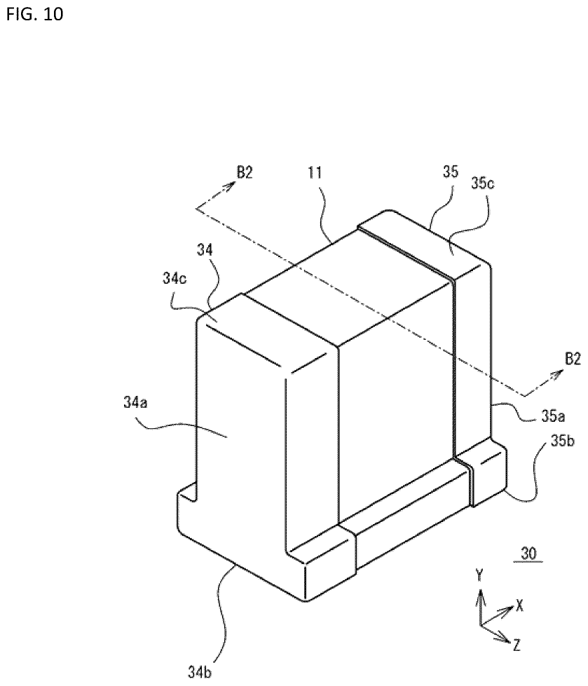

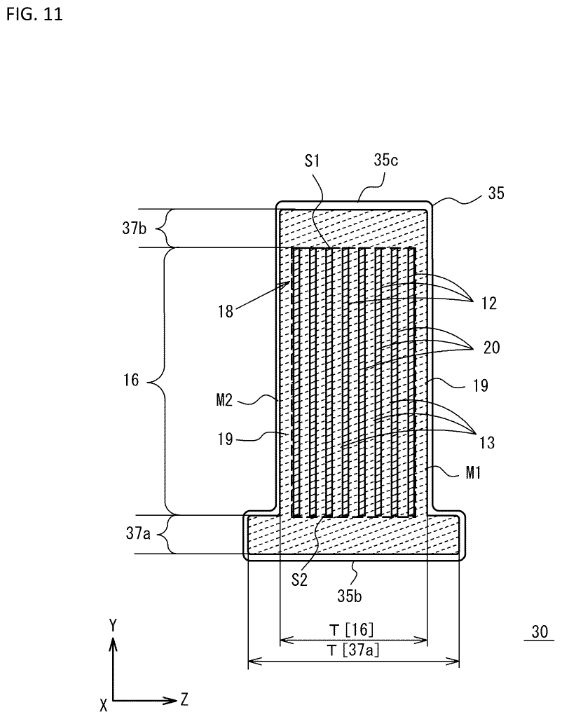

Next, a multilayer ceramic capacitor 30 according to a second embodiment will now be described with reference to FIGS. 10 and 11. FIG. 10 is a perspective view of the multilayer ceramic capacitor 30. FIG. 11 is a cross-sectional view of the multilayer ceramic capacitor 30, taken along line B2-B2 given in FIG. 10.

In the first embodiment, the dimension T[17a] of the first margin part 17a in the Z-axis direction and the dimension of the second margin part 17b in the Z-axis direction are equal to each other and are both set greater than the dimension T[16] of the laminate body 16 in the Z-axis direction. In the second embodiment, only a dimension T[37a] of a first margin part 37a in the Z-axis direction is set greater than the dimension T[16] of the laminate body 16 in the Z-axis direction. The other details are generally the same between the first embodiment and the second embodiment. Therefore, components that are common to the first embodiment are denoted by corresponding reference signs in relevant drawings, and detailed description of such elements is omitted. The dimension T[37a] of the first margin part 37a in the Z-axis direction may be set similarly to the dimension T[17a] of the first margin part 17a according to the first embodiment in the Z-axis direction.

Similarly to the first external electrode 14 according to the first embodiment, a first external electrode 34 includes a first face portion 34a, a second face portion 34b, and a third face portion 34c. Likewise, a second external electrode 35 includes a first face portion 35a, a second face portion 35b, and a third face portion 35c.

Here, the difference between the dimensions of the first margin part 37a and a second margin part 37b in the Z-axis direction makes the areas of the third face portions 34c and 35c smaller than the areas of the second face portions 34b and 35b.

Therefore, when the multilayer ceramic capacitor 30 according to the second embodiment is mounted onto the substrate 1, the side of the first margin part 37a, that is, the side where the second face portions 34b and 35b having the greater areas are located, is made to face the mounting face 1a (see FIG. 4). Similarly to the first embodiment, the multilayer ceramic capacitor 30 designed as above is stably mountable on the substrate 1.

### Third Embodiment

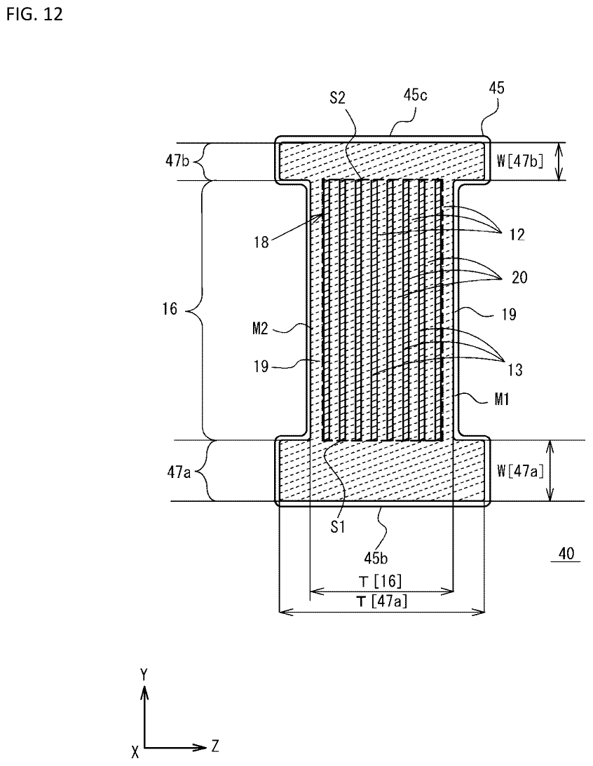

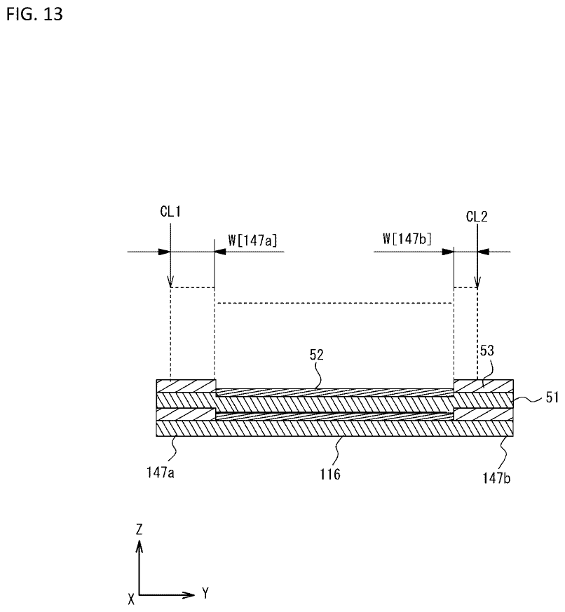

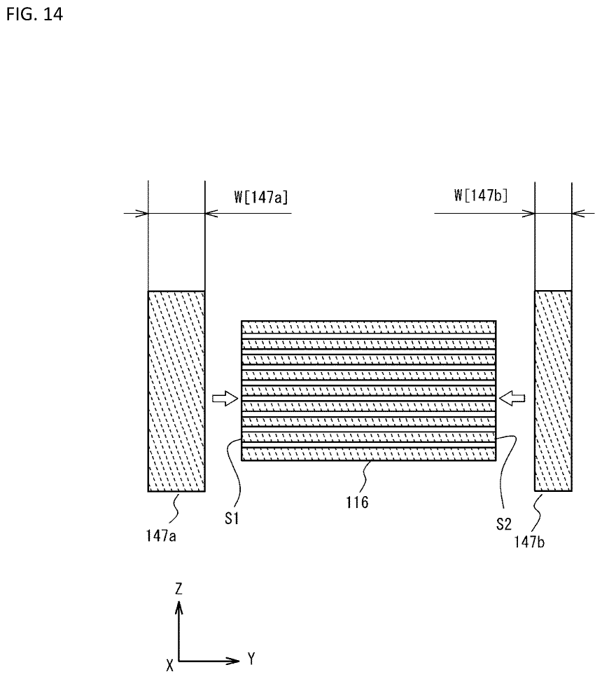

Next, a multilayer ceramic capacitor 40 according to a third embodiment will now be described with reference to FIGS. 12 to 14. FIG. 12 is a cross-sectional view of the multilayer ceramic capacitor 40. FIG. 13 illustrates a step included in a method of manufacturing the multilayer ceramic capacitor 40. FIG. 14 outlines another method of manufacturing the multilayer ceramic capacitor 40.

In the first embodiment, the dimension of the first margin part 17a in the Y-axis direction and the dimension of the second margin part 17b in the Y-axis direction are equal to each other. In contrast, in the third embodiment, a first margin part 47a has a dimension W[47a] in the Y-axis direction that is set greater than a dimension W[47b] of a second margin part 47b in the Y-axis direction. The other details are generally the same between the first embodiment and the third embodiment. Therefore, components that are common to the first embodiment are denoted by corresponding reference signs in relevant drawings, and detailed description of such elements is omitted. A dimension T[47a] of the first margin part 47a in the Z-axis direction is set greater than the dimension T[16] of the laminate body 16 in the Z-axis direction, similarly to the first embodiment.

In the multilayer ceramic capacitor 40 designed as above, the side of the first margin part 47a is to face the substrate 1. The first margin part 47a has a greater dimension in the Y-axis direction than the second margin part 47b. Such an embodiment provides a solution for so-called acoustic noise of the multilayer ceramic capacitor 40.

A multilayer ceramic capacitor that is made of a ferroelectric ceramic material may undergo electrostriction when receiving a voltage at the two ends thereof. Electrostriction is also referred to as a piezoelectric phenomenon and may cause a substrate carrying such a multilayer ceramic capacitor to vibrate, resulting in vibration noise.

In the multilayer ceramic capacitor 40 according to the present embodiment, the first margin part 47a, which is to face the substrate 1, has an increased dimension in the Y-axis direction. Such a design reduces the propagation of vibrations that may occur in the multilayer ceramic capacitor 40 to the substrate 1. Specifically, in the multilayer ceramic capacitor 40, a portion that tends to undergo large expansion and contraction is located away from the mounting face 1a of the substrate 1 (see FIG. 4). Therefore, the propagation of vibrations to the substrate 1 is reduced, which reduces so-called acoustic noise.

The multilayer ceramic capacitor 40 according to the present embodiment has dimensions conforming to a so-called size 0603. Specifically, the multilayer ceramic capacitor 40 has a dimension L in the X-axis direction of 0.6 mm, a dimension T in the Z-axis direction of 0.3 mm, and a dimension W in the Y-axis direction of 0.55 mm. In the multilayer ceramic capacitor 40 designed as above, referring to FIG. 12, the dimension T[47a] of the first margin part 47a in the Z-axis direction is set to 0.3 mm, and the dimension T[16] of the laminate body 16 in the Z-axis direction is set to 0.28 mm. Furthermore, the dimension W[47a] of the first margin part 47a in the Y-axis direction is set to 0.1 mm, and the dimension W[47b] of the second margin part 47b in the Y-axis direction is set to 0.05 mm.

### Manufacturing Method 1

A method of manufacturing the multilayer ceramic capacitor 40 will now be described. The first margin part 47a and the second margin part 47b included in the multilayer ceramic capacitor 40 each have a dimension in the Z-axis direction that is greater than the dimension T[16] of the laminate body 16 in the Z-axis direction. Furthermore, the dimension W[47a] of the first margin part 47a in the Y-axis direction is greater than the dimension W[47b] of the second margin part 47b in the Y-axis direction. The relationship between the dimensions in the Z-axis direction is established by following the method adopted in the first embodiment. The following description relates to components that are relevant to the relationship between the dimensions in the Y-axis direction.

A first margin part 147a, corresponding to the first margin part 47a, and a second margin part 147b, corresponding to the second margin part 47b, are each obtained as a stack of lamination units by cutting a sheet member. Specifically, for the first margin part 147a, the sheet member is cut at a cut line CL1, which defines a dimension W[147a] in the Y-axis direction. For the second margin part 147b, the sheet member is cut at a cut line CL2, which defines a dimension W[147b] in the Y-axis direction. That is, the two dimensions in the Y-axis direction are made to differ by setting the cut lines at different positions from each other.

### Manufacturing Method 2

Next, another method of manufacturing the multilayer ceramic capacitor 40 will now be described with reference to FIG. 14. The manufacturing method illustrated in FIG. 14 is an application of a sheet-pasting method.

In such a manufacturing method, a laminate body 116 that is yet to be fired and a first margin part 147a and a second margin part 147b that are each in a sheet form and yet to be fired are first prepared through publicly known methods. In this step, the dimension W[147a] of the first margin part 147a in the Y-axis direction is set greater than the dimension W[147b] of the second margin part 147b in the Y-axis direction. The first margin part 147a and the second margin part 147b prepared as above are pressed against the first lateral face S1 and the second lateral face S2, respectively, of the laminate body 116 and are thus pasted thereto. Subsequently, these components are sintered, and then external electrodes 14 and 15 are formed thereon. Thus, a multilayer ceramic capacitor 40 is obtained.

It should be noted that while the above embodiments each concern a multilayer ceramic capacitor provided as an exemplary multilayer ceramic electronic component, the multilayer ceramic electronic component is not limited thereto. For example, the configuration according to each of the above embodiments may be applied to another multilayer ceramic electronic component such as a varistor or a thermistor.

The above embodiments are only examples provided for embodying the present invention, and the present invention is not limited thereto. Various changes made to the above embodiments are within the scope of the present invention. Furthermore, it is obvious from the above description that various other embodiments are conceivable within the scope of the present invention.

In this disclosure, in some embodiments, the material/composition constituting dielectric layers, internal electrode layers, margin parts, external electrodes, and perovskite structure may consist of required/explicitly indicated elements described in the present disclosure; however, “consisting of” does not exclude additional components that are known equivalents to the elements and/or unrelated components such as impurities ordinarily associated with the elements. Also, in some embodiments, the term “main component” refers to “primary, majority, or predominant component in terms of quantity or quality, and the term “mainly composed of” refers to “primarily, mostly, or predominantly composed of” in terms of quantity or quality. Further, in some embodiments which are silent as to known components used in this technology field, the known components can explicitly be excluded from the embodiments. Also, in some embodiments, any two numbers of a variable can constitute a workable range of the variable as the workable range can be determined based on routine work, and any ranges indicated may include or exclude the endpoints. Additionally, any values of variables indicated (regardless of whether or not they are indicated with “about”), such as the content of the additive element and the content of copper, may refer to precise values or approximate/rounded values and include equivalents, and may refer to average, median, representative, majority, etc. in some embodiments. In this disclosure, “a” may refer to a species or a genus including multiple species, while a plural may not exclude singular according to the context. Further, “the invention/disclosure” or “the present invention/disclosure” may refer collectively to at least one of the embodiments or examples explicitly or inherently disclosed herein. Also, in some embodiments, any one or more of the disclosed elements or components as options can be exclusively selected or can expressly be excluded, depending on the target piezoelectric ceramic to be manufactured, its target properties, etc., and/or for practical reasons, operational reasons, etc. Additionally, in the present invention/disclosure where conditions and/or structures are not specified, a skilled artisan in the art can readily provide such conditions and/or structures, in view of the present disclosure, as a matter of routine experimentation, etc.

What is claimed is:

1. A multilayer ceramic electronic component comprising:
a laminate body including
a plurality of ceramic layers that are laminated in a first axial direction,
a plurality of internal electrodes that are located between the ceramic layers and that form a capacitance-forming part in combination with the ceramic layers,
a pair of principal faces that are located opposite to each other in the first axial direction,
a pair of lateral faces that are located opposite to each other in a second axial direction orthogonal to the first axial direction, and
a pair of end faces that are located opposite to each other in a third axial direction orthogonal to the first axial direction and to the second axial direction;
a first margin part provided at one side of the laminate body in the second axial direction;
a second margin part provided at another side of the laminate body in the second axial direction; and
a pair of external electrodes provided on the pair of respective end faces,
wherein the pair of external electrodes each include an extended portion extending to and on at least a plane of the first margin part, the plane being defined by the first axial direction and the third axial direction, and
wherein at least the first margin part of the two margin parts has:
a dimension in the first axial direction that is set greater than a dimension of the laminate body in the first axial direction, and
a dimension in the third axial direction that is set in a manner that the first margin part is flush with the pair of end faces of the laminate.

2. The multilayer ceramic electronic component according to claim 1, wherein the dimension of the first margin part in the first axial direction is about 105% to about 110% of the dimension of the laminate body in the first axial direction.

3. The multilayer ceramic electronic component according to claim 1, wherein the second margin part has a dimension in the first axial direction that is set greater than the dimension of the laminate body in the first axial direction.

4. The multilayer ceramic electronic component according to claim 1, wherein the first margin part has a dimension in the second axial direction that is set greater than a dimension of the second margin part in the second axial direction.

5. A package body comprising:
the multilayer ceramic electronic component according to claim 1;
a carrier tape having
a sealing surface that is perpendicular to the second axial direction, and
a recessed part that is recessed relative to the sealing surface in the second axial direction and that accommodates the multilayer ceramic electronic component; and
a top tape pasted to the sealing surface and covering the recessed part.

6. The package body according to claim 5, wherein the dimension of the first margin part in the first axial direction is about 105% to about 110% of the dimension of the laminate body in the first axial direction.

7. The package body according to claim 5, wherein the second margin part has a dimension in the first axial direction that is set greater than the dimension of the laminate body in the first axial direction.

8. The package body according to claim 5, wherein the first margin part has a dimension in the second axial direction that is set greater than a dimension of the second margin part in the second axial direction.

9. A circuit board comprising:
a substrate; and
the multilayer ceramic electronic component according to claim 1 that is mounted on the substrate,
wherein the second axial direction of the multilayer ceramic electronic component coincides with a direction perpendicular to a mounting face of the substrate, and
wherein the extended portion included in the first margin part is placed on a terminal part provided on the mounting face.

10. The circuit board according to claim 9, wherein the dimension of the first margin part in the first axial direction is about 105% to about 110% of the dimension of the laminate body in the first axial direction.

11. The circuit board according to claim 9, wherein the second margin part has a dimension in the first axial direction that is set greater than the dimension of the laminate body in the first axial direction.

12. The circuit board according to claim 9, wherein the first margin part has a dimension in the second axial direction that is set greater than a dimension of the second margin part in the second axial direction.
